(19) United States
(12) Patent Application Publication
(10) Pub. No.: US 2008/0207008 A1
(43) Pub. Date: Aug. 28, 2008

(54) Microwave hybrid and plasma rapid thermal processing of semiconductor wafers

(76) Inventors: Ramesh Peelamedu, Andover, MA (US); David C. Wong, Acton, MA (US)

Correspondence Address: WEINGARTEN, SCHURGIN, GAGNEBIN & LEBOVICI LLP, TEN POST OFFICE SQUARE, BOSTON, MA, 02109, US

(21) Appl. No.: 12/011,009

(22) Filed: Jan. 23, 2008

Related U.S. Application Data
(60) Provisional application No. 60/897,450, filed on Jan. 25, 2007.

(51) Int. Cl. H01L 21/324; H05B 6/64

(52) U.S. Cl. 438/795; 219/756; 257/E21.333

(57) ABSTRACT

Microwave energy is used as a radiation source for rapid thermal processing of semiconductor wafers. In one aspect, a hybrid material formed from a microwave modulator material is used to provide temperature uniformity across the wafer and to avoid cracking or breaking of wafers due to the development of thermal stresses. In another aspect, microwave-generated atmospheric pressure plasma is used to heat the wafer either directly or indirectly.

### CROSS REFERENCE TO RELATED APPLICATIONS

This application claims the benefit under 35 U.S.C. § 119(e) of U.S. Provisional Patent Application No. 60/897,450, filed Jan. 25, 2007, the disclosure of which is incorporated by reference herein.

### STATEMENT REGARDING FEDERALLY SPONSORED RESEARCH OR DEVELOPMENT

N/A

### BACKGROUND OF THE INVENTION

Rapid thermal processing (RTP), employing heating rates on the order of hundreds of degrees per minute, is used in the semiconductor industry wherever a low thermal budget is preferred. For example, a low thermal budget is desired in ultra-small IC manufacturing processes to prevent dopant redistribution. Similarly, in the electronic industries, RTP finds an application in very large scale integration (VLSI) processes, in which the growth of ultra thin gate oxides and activation annealing of ion implanted species are usually done by RTP. In the photovoltaic (PV) industry, RTP is useful for many different purposes, such as phosphorous (P) doping of Si wafers, growth of passivating oxides on the surface, tunnel oxides, metallization, etc.

RTP enables rapid thermal cycles that cannot be performed using a conventional heating procedure such as quartz tube furnaces. Using a conventional furnace, fast heating rates on the order of several hundred degrees/min cannot be achieved. Usually, the process time in RTP equipment ranges between 10⁻⁸-10¹ seconds, which includes heating, soaking, and cooling durations. To achieve such fast heating rates, typically the RTP equipment uses a radiation source such as laser, infra-red, or electron/ion beam sources, or tungsten halogen lamps. If a uni-directional radiation source is used for heating, then the temperature at the middle of the wafer with a thickness ‘d’ is expressed by the following equation:

$$T ( z = d / 2 ) = {T}_{0} erfc ( \frac{d}{4 \sqrt{{D}_{th} t}} )$$

where Tₒ is the temperature measured on the surface of the wafer, Dₜₕ is the thermal diffusivity of silicon, and t is the thermal response time.

### SUMMARY OF THE INVENTION

Microwave energy is used as a radiation source for rapid thermal processing of semiconductor wafers and other substrates capable of absorbing microwaves.

In one aspect, a hybrid material formed from a microwave modulator material is used to provide temperature uniformity across the wafer and to avoid cracking of wafers due to the development of thermal stresses. The hybrid material is also used to avoid edge overheating due to microwave diffraction along the edges.

In one embodiment of the method, a substrate to be heated is disposed in a cavity. A hybrid material comprised of a microwave modulator material is located with respect to the substrate to attenuate microwave radiation prior to reaching at least a portion of the substrate. Microwave radiation is introduced into the cavity to heat the substrate. At least a portion of the microwave radiation is attenuated by the hybrid material prior to reaching the substrate, such that the hybrid material causes heat to be distributed more uniformly to the substrate.

In another aspect, microwave-generated atmospheric pressure plasma is used to heat the wafer either directly or indirectly. A sheath, for example, of a metal material, protects the wafer from contact with the plasma, particularly at the edges.

In one embodiment of the method, a substrate to be heated is enclosed at least partially in a sheath comprised of a heat conductive material. The substrate enclosed in the sheath is disposed in a cavity. The substrate is heated by forming a plasma in the cavity by subjecting a gas in the cavity to microwave radiation, generating a plasma that heats the substrate.

### DESCRIPTION OF THE DRAWINGS

The invention will be more fully understood from the following detailed description taken in conjunction with the accompanying drawings in which:

FIG. 1 is a schematic illustration of a hybrid microwave rapid thermal processing installation;

FIG. 2 is a schematic illustration of microwave modulation;

FIG. 3 is a graph of a time-temperature cycle for hybrid microwave heating of a wafer using an installation such as shown in FIG. 1;

FIG. 4 is a schematic illustration of a microwave-generated plasma rapid thermal processing installation;

FIG. 5 is a graph of a time-temperature cycle of microwave-generated plasma heating of a wafer using an installation such as shown in FIG. 4;

FIG. 6A is a plan view of a sheath having a continuous top plate, for use with the installation of FIG. 4;

FIG. 6B is a plan view of a sheath having a top plate with several openings therein, for use with the installation of FIG. 4; and

FIG. 6C is a plan view of a sheath having a top plate with a single, larger, opening therein, for use with the installation of FIG. 4.

### DETAILED DESCRIPTION OF THE INVENTION

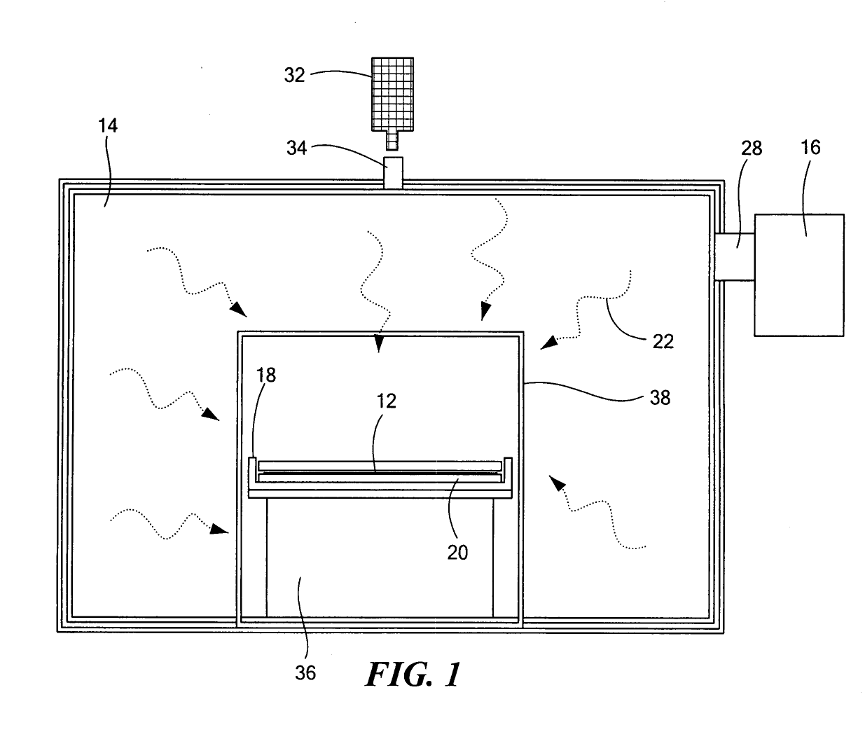

In one aspect of the present invention, a hybrid microwave rapid thermal processing (RTP) method of heating a wafer, for example, a Si wafer, is described generally with reference to FIG. 1. The wafer 12 to be heated is located within a microwave cavity 14 provided with a microwave radiation source (for example, at 2.45 GHz) to heat the wafer. The wafer is also in thermal communication with a hybrid material 18 formed from a suitable microwave modulator material, such as SiC. The hybrid material distributes heat uniformly to the wafer, preventing thermal shock, which could cause cracking or breakage of the wafer, both during heating and cooling. A buffer or insulation layer 20 is placed between the hybrid material and the wafer or underlying support pedestal if necessary to prevent diffusion of the hybrid material into the wafer and/or the pedestal. For example, SiC from the hybrid material can diffuse C species into a Si wafer. Quartz forms a suitable buffer layer, because it does not absorb microwaves or thermal energy, so it does not affect the thermal process.

As noted above, the hybrid material 18 distributes heat uniformly across the wafer 12 to prevent the wafer from cracking or breaking up due to the development of internal thermal stresses. The hybrid modulator material is preferably a room temperature secondary microwave susceptor that has moderate microwave absorbing characteristics compared to the wafer. The hybrid material attenuates the microwave radiation 22 reaching the wafer and may also transfer heat to the wafer by conduction. In addition, microwave diffraction phenomena from the edges of the wafer can lead to undesirable overheating of the edges. Thus, the modulator material also preferably extends about the edge periphery of the wafer to minimize or eliminate excessive heating at the edges. A porous, partially sintered SiC, having a porosity of 20 to 30%, is a suitable modulator material, because it can be heated and cooled multiple times without cracking or breaking apart. Some magnetic ferrites can also be used.

More particularly, microwave absorption for planar thick samples can be characterized by a parameter termed the penetration depth, Dₚ. The penetration depth for microwaves in a homogeneous ceramic material is given by the following equation:

$${D}_{p} = \frac{{λ}_{o}}{2 π tan δ \sqrt{{ɛ}_{r}}}$$

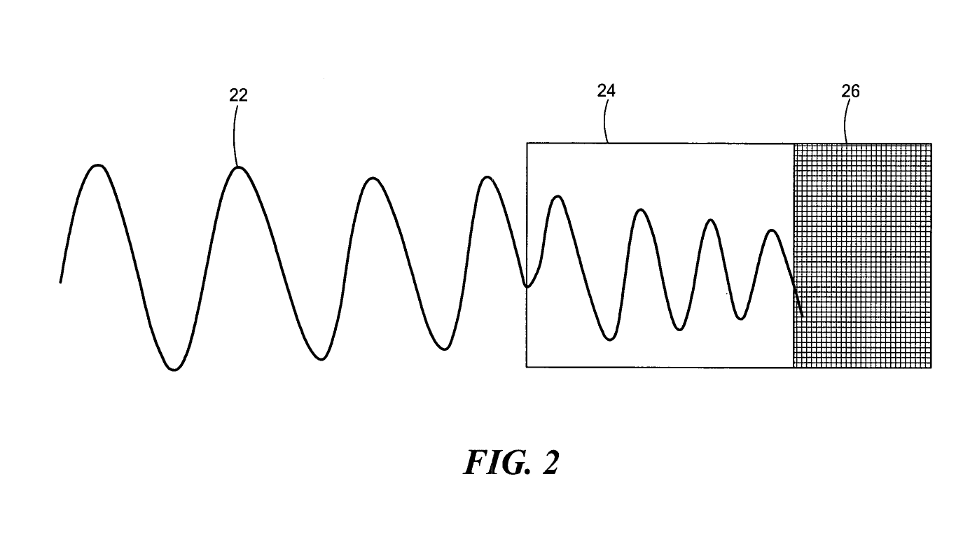

At a frequency of 2.45 GHz, the free space wavelength λₒ=122.4 μm. The tan δ and εᵣ are respectively the tangent loss factor and the dielectric permittivity values for the hybrid materials considered, which can be obtained from the technical literature. In an arrangement in which a room temperature susceptor is used as a modulator, the above equation can be used to calculate the microwave attenuation inside the modulator. The concept of attenuation in the modulator material is depicted schematically in FIG. 2, which illustrates microwave radiation 22 transmitted through a modulator material 24 before reaching a sample workpiece 26.

For example, SiC is a suitable modulator material when placed around a Si wafer. The Dₚ calculation using the above equation shows that, at room temperature, microwaves penetrate into SiC to a depth of approximately 10 mm from every side. Thus, a 20 mm thick SiC piece can completely block microwaves reaching the wafer on a given side. At 500° C., the penetration depth value in SiC reduces to approximately 5 mm and at this temperature, a 10 mm bulk piece of SiC material is capable of blocking microwaves reaching the wafer. If microwaves are completely blocked from the wafer, wafer heating is predominantly by a simple heat transfer mechanism from the SiC plate. On the other hand, a SiC thickness of less than 1 mm can allow excess microwave energy to reach the wafer, resulting in edge heating due to the “diffraction effect.” Hence, the modulator thickness is chosen preferably to keep the modulator attenuation at less than 50%, so that at least 50% of microwave energy can reach the wafer. Similarly, the modulator material should not completely enclose the wafer or too little microwave energy would reach the wafer. For example, the modulator material generally does not need to cover the top surface of the wafer to allow the top surface to be exposed to microwaves.

In a large industrial system, the process becomes more a volumetric phenomenon and the modulator and wafer arrangement can have a variety of configurations. For example, in one such arrangement, the modulator material can be spaced a distance away from the wafers. This arrangement provides heat mostly by radiative transfer mechanisms with the absence of partial heat by conduction. Also, the modulator material can take a variety of configurations, such as a plate or a number of thin rods. A crucible-shaped modulator can be configured to match the shape of the wafer, such as a cylindrical crucible for a circular wafer. If the wafer is square or rectangular, the crucible can be shaped accordingly. Whatever arrangement the modulator takes, the above power balance between the modulator and wafer is taken into account.

Any suitable microwave radiation source 16 can be used to generate the microwaves, such as a magnetron, klystron, or any other source of microwave energy. The microwave radiation source can direct microwave radiation into the cavity 14 through one or more waveguides 28, or it can be connected directly to the cavity, eliminating the waveguide. The cavity 14 can be single mode or multi-mode. For large scale industrial applications, multi-mode microwave cavities are more suitable than the size-constrained single mode cavities. A pyrometer 32 for measuring the temperature of the wafer may be provided through a view port 34 in a cavity wall. For optimum microwave absorption, the wafer is preferably supported centrally in the cavity. A pedestal 36 of a material, such as fibrous alumina, that does not absorb microwave radiation or thermal energy is suitable. A suitable controller (not shown) in communication with the microwave radiation source and other components is preferably used to control the process.

The wafer can also be located in an interior chamber 38 within the cavity, for example, to prevent contamination of the wafer or to contain a gas that may be introduced. The chamber is suitably formed of quartz, which does not obstruct vision of the wafer and does not absorb microwaves or thermal energy. The cavity 14 can be insulated to achieve high heating rates. The process can be sized for multiple wafers at one time. Also, while the process has been described as a batch process, it can be adapted to a continuous process.

In one exemplary embodiment, the wafer 12 to be heated is sandwiched between two clean quartz plates that constitute the buffer 20. The top plate can either be solid or include perforations through its thickness. The top plate prevents or minimizes direct contact between the wafer and the ambient atmosphere, to minimize or avoid convective heat losses, which helps to keep the wafer heating rates high. This arrangement is placed inside a cylindrical crucible, which is made of a modulator material 18. The height of the crucible is just equal to or slightly higher than the quartz and wafer sandwich arrangement. Such an arrangement can be used to heat even large wafers rapidly.

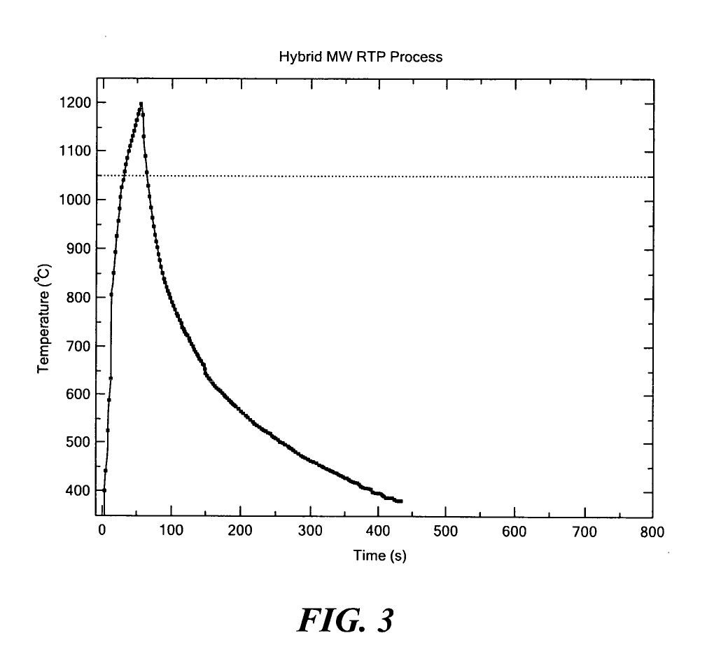

Experiments were performed to test the microwave heating of a Si wafer in a multi-mode microwave cavity using an arrangement as shown in FIG. 1 with a crucible of a SiC modulator material and quartz buffer. Rapid heating to temperatures of 1000° C. and above followed by rapid cool down to room temperature without the breakage of the wafers was achieved by the hybrid microwave procedure described here. FIG. 3 illustrates a time-temperature cycle in which a Si wafer was heated using an arrangement as shown in FIG. 1. The time-temperature cycle is comparable to existing RTP methods and illustrates that a low thermal budget (the area under the t-T curve) is possible. A comparison of a Si wafer heated in the microwave environment both with and without the modulator showed the intensity of edge heating is considerably reduced when the modulator material is present.

This process is advantageous in saving power, because the heating process takes place only on the wafer. For example, in the experiments that were performed, the microwave input power did not exceed 800 W to heat small sized samples.

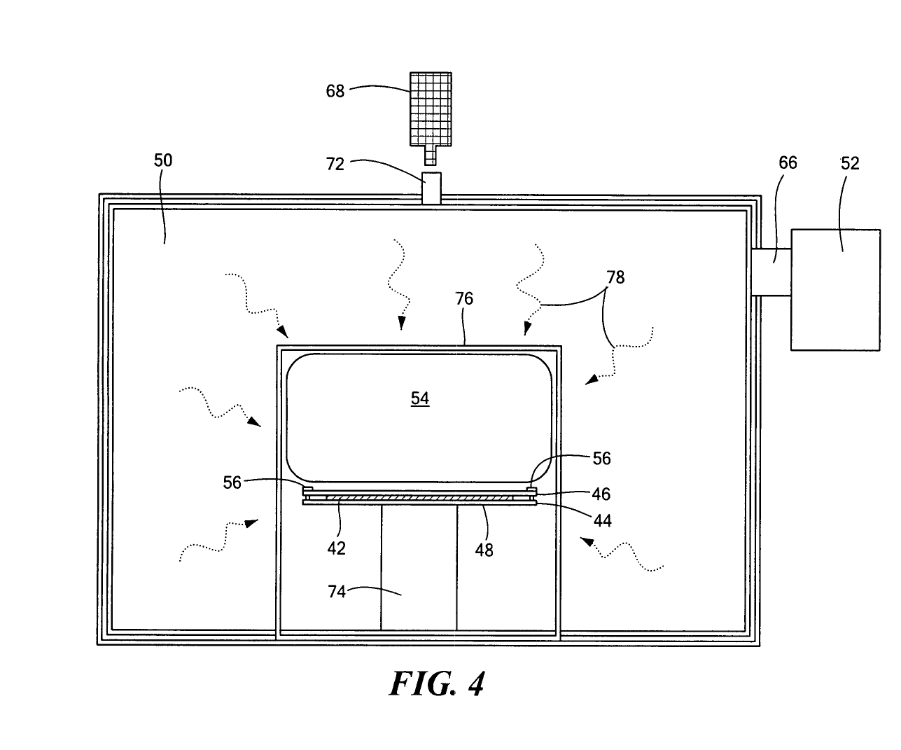

In another aspect of microwave-based rapid thermal processing, microwave energy is used first to create an atmospheric pressure plasma above a wafer surface, and the plasma in turn rapidly heats the wafer, described generally with reference to FIG. 4. Microwave generation of a plasma is generally known. See for example US Published Patent Application No. US 2005-0233091, the disclosure of which is incorporated by reference herein.

The wafer 42 to be heated is enclosed within a metal sheath 44 formed of top and bottom plates 46, 48 fastened together in any suitable manner, such as with a pair of screws 56, with the wafer sandwiched in between the plates. The wafer in the sheath is located within a microwave cavity 50 provided with a microwave radiation source 52 to generate a plasma 54 for heating the wafer. The sheath 44 conducts heat to the wafer while protecting the wafer from contact with the plasma 54, which could react with or melt the wafer in some cases.

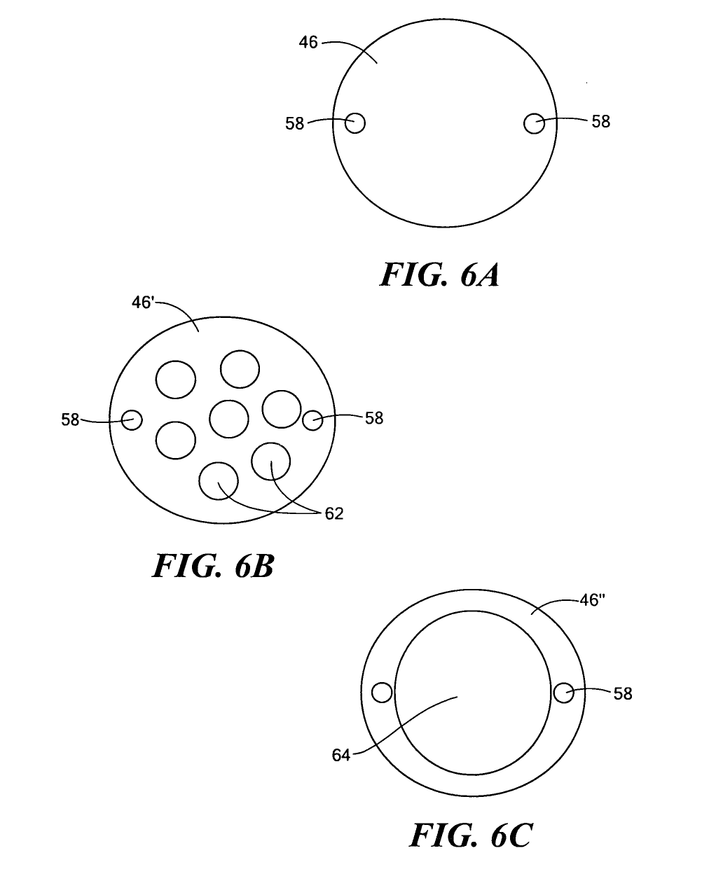

In one embodiment, the top plate 46 of the metal sheath 44 is continuous (see FIG. 6A), covering the entire wafer surface, to prevent contact of the plasma with the wafer while still conducting heat to the wafer. Holes 58 for the screws 56 are provided near the edges. In this case, heating from the plasma is indirect as a radiant heat source. In some cases, some contact of the plasma with the wafer is acceptable to increase heating due to impingement of ionic species. Too much of the plasma volume, however, should not touch the surface directly, as this can etch out surface phosphorous by sputtering despite providing high heating rates. In this case, a perforated top plate can be used. The sheath should, however, cover the periphery of the wafer to prevent excessive heating at the wafer's edge. Two embodiments of a perforated sheath top plate are shown in FIGS. 6B and 6C. FIG. 6B illustrates a top plate 46′ with several openings 62 therein. FIG. 6C illustrates a top plate 46″ with a single, larger, opening 64. The size and number of openings is selected based on heating need with regard to preventing surface etching.

Certain metals are suitable materials for the sheath, because they are capable of conducting heat rapidly to the wafer and are relatively inexpensive. The metal has a melting temperature sufficiently high, for example, greater than 1000° C., so that it does not melt in the cavity. The surface of the sheath preferably has a polished finish for good contact with the wafer. Suitable metals include an austenitic nickel-based superalloy, such in INCONEL®, and stainless steel.

Any suitable microwave radiation source 52 can be used to generate the microwaves, such as a magnetron, klystron, or any other source of microwave energy. The microwave radiation source can direct microwave radiation into the cavity through one or more waveguides 66, or it can be connected directly to the cavity, eliminating the waveguide. The cavity can be single mode or multi-mode. For large scale industrial applications, multi-mode microwave cavities are more suitable than the size-constrained single mode cavities. Suitable insulation can be provided for the cavity to increase the heating rates. A pyrometer 68 for measuring the temperature of the wafer may be provided through a view port 72 in a cavity wall. For optimum heating, the wafer is preferably supported centrally in the cavity. A pedestal 74 of a material, such as fibrous alumina, that does not absorb microwave radiation or thermal energy is suitable.

The wafer is preferably located within an interior chamber or vessel 76 to contain the plasma 54. The cavity or vessel is connected to one or more gas sources (such as a source of argon, nitrogen, hydrogen, xenon, krypton, etc.) by a line and a control valve (not shown). The microwave radiation 78 entering the cavity or vessel ignites the plasma within. An optional passive or active plasma catalyst can be added to the cavity or vessel for initiating, modulating, and sustaining the plasma.

A suitable controller (not shown) in communication with the microwave radiation source, the gas source, and other components is preferably used to control the process. The process can be sized for multiple wafers at one time, as long as the plasma is suitable confined. Also, while the process has been described as a batch process, it can be adapted to a continuous process, similarly as long as the plasma is suitable confined.

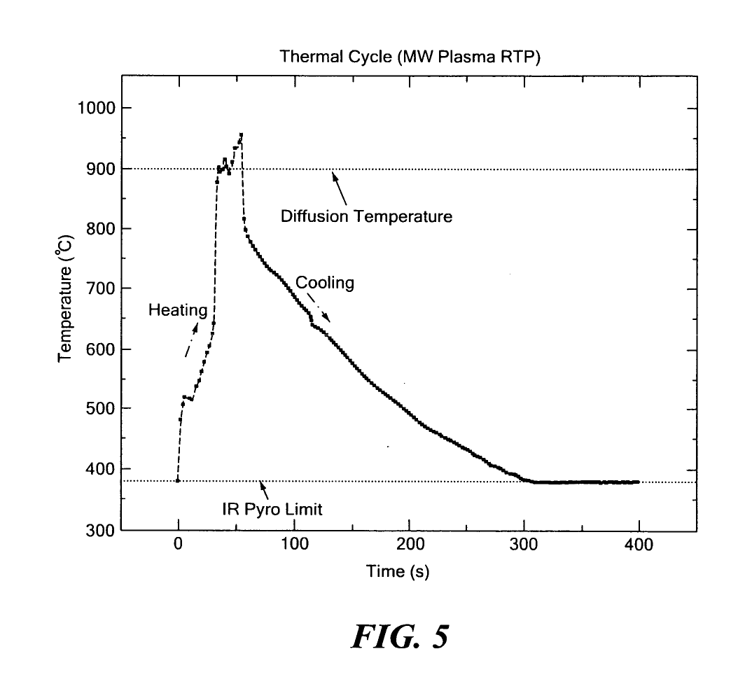

Experiments were performed to test plasma microwave heating of a Si wafer in a multi-mode microwave cavity using an arrangement as shown in FIG. 4 with an INCONEL® metal sheath enclosing the wafer. Rapid heating to temperatures of 900° C. and above followed by rapid cool down to room temperature without breakage of the wafers was achieved by this process. The time-temperature graph obtained in this experiment is shown in FIG. 5. The time-temperature cycle is comparable to existing RTP methods and illustrates that a low thermal budget is possible with the plasma microwave heating process.

The wafer sheet resistance was measured using a four probe resistivity procedure. The values measured on both hybrid microwave and plasma microwave RTP processed samples were comparable to that of the samples processed using existing RTP procedures, indicating the formation of shallow to deep p-n junctions with both the hybrid and plasma microwave processes.

The hybrid and plasma microwave RTP processes described provide several advantages with respect to current RTP equipment and processes. Most of the current RTP machines are available as single wafer reactors. The hybrid and plasma microwave RTP equipment can be developed with large areas having higher throughputs.

In current RTP machines using tungsten halogen lamps as an energy source, the energy transfer mechanism occurs as a two step process. First, the tungsten filament in the halogen source has to be electrically heated to 2000 to 3000 K before the wafers start absorbing the light energy. Although the lamp heating is energy efficient compared to conventional furnace processing (CFP), the efficiency is still not as high as the described microwave heating technology.

Lamp heating is directional and more efficient on the exposure surface of the wafer compared to the bottom surface. Hence, gold plated reflectors in addition to several lamp sources are required for efficient volumetric heating. In contrast, microwave heating is inherently a volumetric heating process.

Light absorption is thickness dependent, and non-uniform heating is usually a problem with large surface wafers. The present hybrid and plasma microwave heating provides more uniform heating of large surface wafers.

The processes have been described in conjunction with a Si wafer. Other wafer materials can be heated with this process, such as GaAs (gallium arsenide), GaP (gallium phosphide), GaN (gallium nitride), Ge (germanium), InP (indium phosphide), ZnO (zinc oxide), SiC (silicon carbide), CdSe (cadmium selenide), CdTe (cadmium telluride), ZnS (zinc sulfide), ZnSe (zinc selenide), and ZnTe (zinc telluride) wafers, and other materials known to those of skill in the art.

The invention is not to be limited by what has been particularly shown and described, except as indicated by the appended claims.

What is claimed is:

1. A hybrid microwave process for rapid thermal processing of a substrate, comprising:
disposing a substrate to be heated in a cavity;
providing a hybrid material comprised of a microwave modulator material, the hybrid material located with respect to the substrate to attenuate microwave radiation prior to reaching at least a portion of the substrate; and
introducing microwave radiation into the cavity to heat the substrate, at least a portion of the microwave radiation attenuated by the hybrid material prior to reaching the substrate, wherein the hybrid material causes heat to be distributed more uniformly to the substrate.

2. The process of claim 1, wherein the hybrid material has a thickness to allow at least 50% of microwave energy to reach the wafer.

3. The process of claim 1, wherein the hybrid material has a configuration to allow at least 50% of microwave energy to reach the wafer.

4. The process of claim 1, wherein the hybrid material is disposed to attenuate microwave radiation reaching edges of the substrate.

5. The process of claim 1, wherein the hybrid material is disposed in thermally conductive contact with one surface and edges of the substrate.

6. The process of claim 1, wherein the hybrid material comprises a plate.

7. The process of claim 1, wherein the hybrid material comprises a plurality of rods.

8. The process of claim 1, wherein the hybrid material comprises a crucible having a bottom surface and edges configured to match the substrate.

9. The process of claim 1, wherein the hybrid material is spaced from the substrate.

10. The process of claim 1, wherein the hybrid material comprises silicon carbide.

11. The process of claim 1, wherein the hybrid material comprises a magnetic ferrite material.

12. The process of claim 1, further comprising disposing a buffer between the substrate and the hybrid material, the buffer comprised of a material that absorbs substantially no microwave radiation.

13. The process of claim 12, wherein the buffer material comprises quartz.

14. The process of claim 12, wherein the buffer comprises a top plate and a bottom plate, the substrate sandwiched between the top plate and the bottom plate.

15. The process of claim 14, wherein the top plate of the buffer is continuously solid.

16. The process of claim 14, wherein the top plate of the buffer is perforated.

17. The process of claim 1, further comprising disposing the substrate in an interior chamber within the cavity.

18. The process of claim 1, wherein the substrate comprises a semiconductor wafer.

19. The process of claim 1, wherein the substrate is comprised of silicon, gallium arsenide, gallium phosphide, gallium nitride, germanium, indium phosphide, zinc oxide, silicon carbide, cadmium selenide, cadmium telluride, zinc sulfide, zinc selenide, or zinc telluride wafer materials.

20. The process of claim 1, wherein the cavity is a single mode or a multi-mode cavity.

21. The process of claim 1, wherein the cavity is insulated.

22. A plasma microwave process for rapid thermal processing of a substrate, comprising:
enclosing a substrate to be heated at least partially in a sheath comprised of a heat conductive material;
disposing the substrate enclosed in the sheath in a cavity;
heating the substrate by forming a plasma in the cavity by subjecting a gas in the cavity to microwave radiation, whereby the plasma heats the substrate.

23. The process of claim 22, wherein the sheath encloses at least edges of the substrate.

24. The process of claim 22, wherein the sheath comprises a top plate and a bottom plate, the substrate sandwiched between the top plate and the bottom plate.

25. The process of claim 24, wherein the top plate of the sheath is continuously solid.

26. The process of claim 24, wherein the top plate of the sheath is perforated.

27. The process of claim 22, wherein the sheath is comprised of a metal.

28. The process of claim 22, wherein the sheath is comprised of an austenitic nickel-based superalloy or stainless steel.

29. The process of claim 22, further comprising providing a plasma catalyst in the cavity for initiating, modulating, and sustaining the plasma.

30. The process of claim 22, wherein the plasma is formed at atmospheric pressure.

31. The process of claim 22, further comprising disposing the substrate in an interior chamber within the cavity.

32. The process of claim 22, wherein the substrate comprises a semiconductor wafer.

33. The process of claim 22, wherein the substrate is comprised of silicon, gallium arsenide, gallium phosphide, gallium nitride, germanium, indium phosphide, zinc oxide, silicon carbide, cadmium selenide, cadmium telluride, zinc sulfide, zinc selenide, or zinc telluride wafer materials.

34. The process of claim 22, wherein the cavity is a single mode or a multi-mode cavity.

35. The process of claim 22, wherein the cavity is insulated.
